(19) United States
(12) Patent Application Publication
(10) Pub. No.: US 2002/0050936 A1
(43) Pub. Date: May 2, 2002

(54) USB machine

(76) Inventors: Tetsuya Kato, Kitaiso Sayama-shi (JP); Tatsuo Nishimaki, Fussa-shi (JP); Kazuhiro Sendo, Iruma-shi (JP)

Correspondence Address: J.C. Patents, Inc., Suite 250, 4 Venture, Irvine, CA, 92618, US

(21) Appl. No.: 09/962,711

(22) Filed: Sep. 24, 2001

(30) Foreign Application Priority Data
Oct. 30, 2000 (JP) 2000-331406

(51) Int. Cl. H03M 9/00

(52) U.S. Cl. 341/100

(57) ABSTRACT

A self-powered USB machine. A power control switch 23 is installed in a main power circuit 21 of the USB machine. By detecting whether a voltage occurs at a +5V power terminal of a USB port, the power control switch 23 is turned on or off. A pull-up resistor 17 is connected to a switch 18 in series. And, the pull-up switch 18 is turned on or off after the power control switch 23 is turned on or off. Thereby, the power consumption is reduced.

### CROSS-REFERENCE TO RELATED APPLICATION

This application claims the priority benefit of Japanese application serial no. 2000-331406, filed on Oct. 30, 2000.

### BACKGROUND OF THE INVENTION

1. Field of the Invention

This invention relates in general to a USB machine, such as a CD-ROM, CD-R, CD-RW device with a USB interface, and more particularly relates to a USB machine that is a self-powered device.

2. Description of Related Art

A cable complying with a USB (universal serial bus, USB) interface consists of two power lines and two signal lines. Machines capable of being driven by the power lines in the USB cable are bus-powered devices, and machines having a power source other than the USB cable are self-powered devices. The invention is related to the self-powered devices.

In addition, in regard to the USB machines, a host device can automatically identify both the USB device connected to the host device and the data-transferring rate of the USB device. For the automatic identification, if the data transferring rate is in a full-speed mode, a signal line of the “plus” side D+ is connected to a pull-up power source through a resistor of 1.5 KΩ, while if the data transferring rate is a low-speed mode, a signal line of the “minus” side D− is connected to the pull-up power source through a resistor of 1 5 KΩ.

Conventionally, under the condition of use of the self-powered devices, the devices can be operated only both powers of the host device (personal computer, PC) and the USB device are turned on. If one of the powers is forgotten to be turned on, the USB machine cannot be operated normally. In addition, it is possible to keep the self-powered device turned on constantly, which however causes an unnecessary vain loss of power. Moreover, when the host device has to be turned off for any problem, if the self-powered device is turned off and not initialized, it cannot be started.

For solving such a problem, a power device for the USB machine is installed. However, the computer system becomes complex and its cost is increased because the power is independently installed.

Furthermore, a pull-up power for automatically identifying the connected USB machine and the data transfer rate is turned on at the time that the power of the self-powered device is on, the automatic identification becomes unstable, and therefore a protocol error may occur.

### SUMMARY OF THE INVENTION

According to the foregoing description, an objective of this invention is to provide a USB machine capable of reducing power loss of the self-powered USB machine.

It is another objective of the invention to provide a USB machine capable of reducing occurrences of protocol errors and the power loss of the self-powered USB machine.

According to the objectives mentioned above, the invention provides a self-powered USB machine. The self-powered USB machine comprises a USB port having signal terminals and power terminals; a self-powered power terminal; a control circuit receiving power from the self-powered power terminal or from the power terminals of the USB port, for detecting whether a voltage occurs at the power terminals of the USB port to generate a detected signal, and then outputting a control signal using the detected signal; a USB power circuit coupled to the self-powered power terminal and the control circuit, for sending out a USB driving voltage in response to the control signal that indicates a voltage generated from the control circuit occurs at the power terminals of the USB port, and for stopping sending out the USB driving voltage in response to the control signal that indicates no voltage occurs at the power terminals of the USB port; and a USB main entity coupled to the USB power circuit and the signal terminals of the USB port

The self-powered USB machine above further comprises a series-connected circuit and a pull-up switch delay control circuit. The series-connected circuit consists of a pull-up resistor and a pull-up switch for connecting the pull-up resistor, wherein the pull-up resistor is coupled between the signal terminals of the USB port and one of the USB power circuit, the power terminals of the USB port or a pull-up power circuit. The pull-up switch delay control circuit is used for delaying a predetermined time from a time point of a signal generated to indicate that the USB power circuit sends out the USB driving voltage, thereby the pull-up switch is turned on after the predetermined time.

The self-powered USB machine further comprises an auxiliary power circuit for driving the control circuit, wherein the auxiliary power circuit is constantly connected to the self-powered power terminal.

The invention further provides a self-powered USB machine described below as claimed. The self-powered USB machine comprises a USB port having signal terminals and power terminals; a self-powered power terminal; a control circuit receiving power from the self-powered power terminal or from the power terminals of the USB port, for detecting whether a voltage occurs at the power terminals of the USB port to generate a detected signal, and then outputting a control signal using the detected signal; a USB power circuit coupled to the self-powered power terminal and the control circuit, for sending out a USB driving voltage in response to the control signal generated from the control circuit that indicates a voltage occurs at the power terminals of the USB port, and for stopping sending out the USB driving voltage in response to the control signal that indicates no voltage occurs at the power terminals of the USB port; and a USB main entity coupled to the USB power circuit and the signal terminals of the USB port. The USB power circuit further comprises a rectifying/smoothing circuit connected to the self-powered power terminal, and a switching regulator connected to the rectifying/smoothing circuit, and the switching regulator has a switching device for voltage regulation. Additionally, the control circuit enables a voltage-control operation for the switching device in response to that a voltage occurs at the power terminals of the USB port, and disables the voltage-control operation to turn off the switching device to stop sending out the USB driving voltage in response to that no voltage occurs at the power terminals of the USB port.

According to the embodiments, the power is supplied from the main power circuit of the USB machine when a voltage occurs at the power terminals of the USB port, and the power supply is stopped from the main power circuit of the USB machine when no voltage occurs at the power terminals of the USB port, so the power consumption of the main power circuit and the main entity of the USB machine can be significantly reduced.

In addition, the pull-up resistor and the switch are connected in series to the signal terminal of the USB port and the switch is turned off when no voltage occurs at the power terminal of the USB port, thus it can significantly reduce the power consumption of the USB machine.

Furthermore, the switch for connecting the pull-up resistor is turned on after the power is supplied to the main power circuit of the USB machine, and therefore it can avoid an occurrence of the protocol errors.

Due to the fact that the power control circuit and the delay control circuit are driven by the auxiliary power circuit, the control circuits can be operated in a stable and fast way.

The switching device for voltage regulation can be used for implementing the on/off of the USB power circuit, and therefore required circuit elements and cost can be reduced.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings in which:

FIG. 1 is a block diagram showing a system using a USB machine according to the first embodiment of the invention;

FIG. 2 is a flow chart showing an operation of the USB machine in FIG. 1; and

FIG. 3 is a schematic circuit diagram showing a main power circuit according to the second embodiment of the invention.

### DESCRIPTION OF THE PREFERRED EMBODIMENT

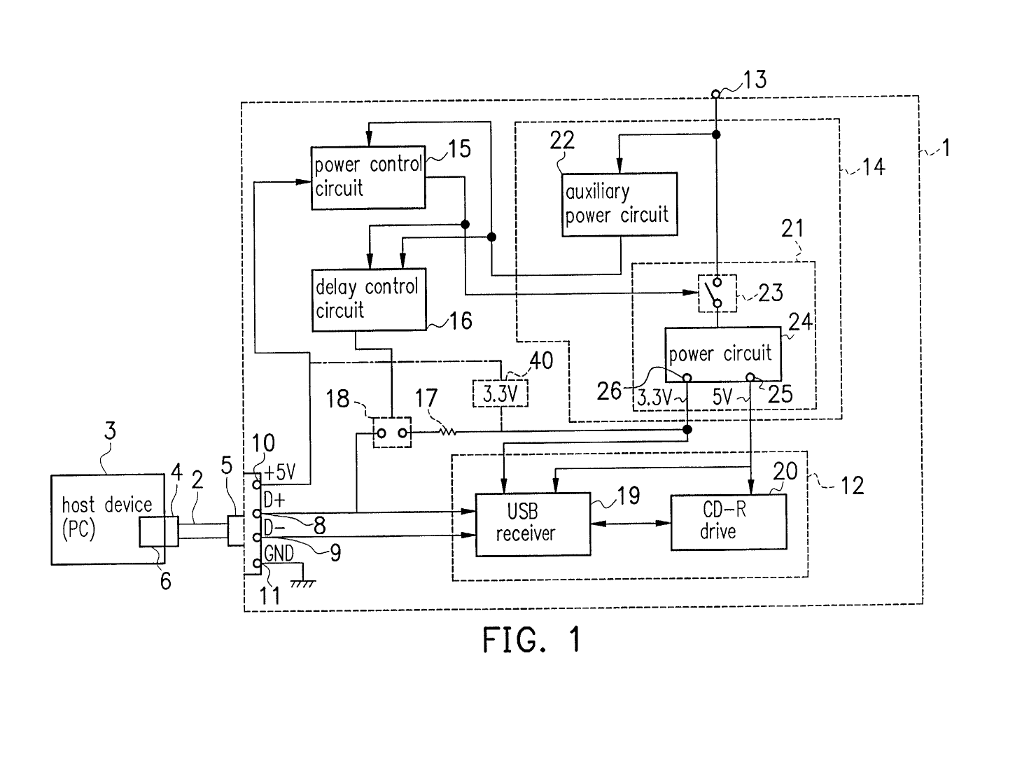

Accompanying with the drawings of FIGS. 1˜3, embodiments of the invention are described and discussed in detail as follows.

### First Embodiment

FIG. 1 shows a USB machine according to the first embodiment of the invention. A USB machine 1 is connected through a USB cable 2 to a host device 3 which is another USB machine. The USB cable 2 comprises a first connector 4 and a second connector 5, and a connector 6 of the host device 3 and a connector 7 serving as a port of the USB machine 1 are attachablly connected. The USB cable comprises a positive (plus) signal line D+, a negative (minus) signal line D−, a first power line of +5V and a second power line of ground.

Referring to FIG. 1, in the USB machine 1, the connector 7 serving as the port of the USB machine 1 comprises a first signal terminal 8 connected to the positive (plus) signal line D+, a second signal terminal 9 connected to the negative (minus) signal line D−, a first power terminal 10 connected to the first power line of +5V and a second power terminal 11 connected to the ground (the second power line).

As shown in FIG. 1, the self-powered USB machine 1, for example a CD-R device, substantially comprises a main entity 12 of the USB machine 1, a self-powered power terminal 13, a USB power circuit 14, a power control circuit 15, a delay control circuit 16, a pull-up resistor 17, a switch 18 for connecting to the pull-up resistor 17.

The main entity 12 of the USB machine 1 consists of the known USB receiver 19 and the known CD-R drive 20 serving as a data converter device or a disc memory device. The USB receiver 19 is coupled to the first and the second signal terminals 8, 9 and the CD-R drive 20. Communication is executed between the host 3 and the CD-R drive 20 through a built-in USB interface circuit (not shown) in the USB receiver 19 and a control circuit (not shown) in the CD-R drive 20. By this communication, control from the host 3 to the CD-R drive 20 is established. The CD-R drive 20 is constituted to record and reproduce data by irradiating light beams onto an optical recording medium. Additionally, according to the embodiment of the invention, the CD-R drive 20 has a fill-speed data transfer mode.

The self-powered power terminal 13 can be a terminal for connecting to a commercial alternative current (AC) power of 50 Hz or 60 Hz, or a plug for plugging into a socket of the commercial AC power.

The USB power circuit 14 comprises a main power circuit 21 and an auxiliary power circuit 22. The main power circuit 21 consists of a power control switch 23 and a power circuit 24. The power circuit 24 is connected to the self-powered power terminal 13 through the power control switch 23. The power circuit 24 includes the rectifying/smoothing circuit for rectifying and smoothing AC 100V, and the known voltage control circuit for supplying constant voltage of DC 5V and 3.3V. The 5V output terminal 25 of the power circuit 24 is connected to the USB transceiver/receiver 19 and the power terminal of the CD-R drive 20. The 3.3V output terminal 26 of the power circuit 24 is connected to the USB transceiver/receiver 19 and the first signal terminal 8 through the pull-up resistor 17 and the switch 18.

The auxiliary power circuit 22, also called a stand-by power circuit, is coupled to the self-powered power terminal 13. Then, an AC voltage of 100V is rectified and smoothed to a DC voltage of 5V, and the 5V DC voltage is transmitted to power terminals of the power control circuit 15 and the delay control circuit 16.

The power control circuit 15 is connected to the +5V power terminal 10 of the USB port for detecting whether the power terminal 10 is at a predetermined voltage of +5V and controls the power control switch 23 of the main power circuit 21. Because the power control circuit 15 is driven by the auxiliary power circuit 22, the power control circuit 15 can be rapidly operated irrelevant to the on/off of the switch 23. The switch 23, for example, can be a semiconductor switch made of transistors or a magnetic switch. A control signal from the power control circuit 15 is supplied to the control terminal of the switch 23.

The delay control circuit 16 is coupled between the power control circuit 15 and a control terminal of the switch 18 connected to the pull-up resistor 17, and is used to generate a control signal to the switch 18 for the a purpose of a necessary delay of the initialization of the USB machine by delaying the control signal outputted from the power control circuit 15 for such as several milliseconds (ms) or seconds (s). The delay control circuit 16 is driven by the auxiliary power circuit 22 for transmitting the control signal to the control terminal of the switch 18 that is made of a semiconductor or a magnetic switch. As described above, because the CD-R drive is a device of a full-speed mode, the signal terminal 8 at the “plus” side is pulled up by turning on the switch 18, and then the host device 3 recognizes that the CD-R drive 20 is connected to the host device 3 and additionally the CD-R drive 20 is a device of the full-speed mode. In addition, in the case of a low-speed mode slower than a full-speed one, the pull-up resistor 17 and the switch 18 are to be connected in series to the second signal terminal 9 (the “minus” side of the USB cable 2).

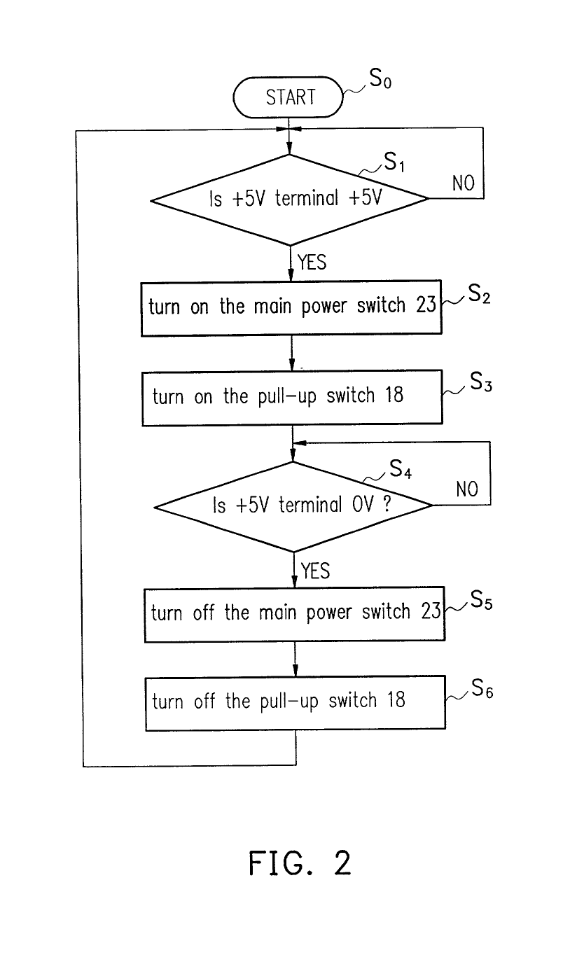

FIG. 2 shows a flow chart for the operation of the power control circuit 15 and the delay control circuit 16 in FIG. 1. First, the operation is started at the step S0 in response to that power is supplied to self-powered power terminal 13. Next, at the step S1, it is determined that whether a voltage of +5V is occurred at the +5V terminal 10. If the +5V terminal 10 is +5V (“YES”), a control signal is sent out to turn on the main power switch 23 at the step S2. Later, at the step S3, the switch 18 for connecting the pull-up resistor 17 is turned on by the delay control circuit 16. At step S4, it determines that whether a voltage of 0V is occurred at the +5V terminal 8. If the voltage at the +5V terminal 10 is changed to 0V (“YES”), the main power switch 23 is then turned off at the step S5. Thereafter, the switch 18 for connecting the pull-up resistor 17 is turned off at the step S6 and then returns to the step S1. Additionally, the steps S5 and S6 can be changed without affecting the normal operation of the invention.

As the foregoing description, the first embodiment of the invention has at least advantages:

(1) When a voltage occurs at the power terminal 10 of the USB port, the power is supplied from the main power circuit 21 of the USB machine 1, and when no voltage occurs at the power terminal 10 of the USB port, the power supply is stopped from the main power circuit 21 of the USB machine 1, therefore an unnecessary power consumption can be reduced in the main power circuit 21 and main entity 12 of the USB machine 1.

(2) Because the pull-up resistor 17 and the switch 18 are connected in series and the switch 18 is turned off when no voltage occurs at the power terminal of the USB port, and an unnecessary power consumption can be reduced.

(3) Because the switch 18 for connecting the pull-up resistor 17 is turned on after the start of power supply by the main power circuit 21 of the USB machine 1, it can avoid an occurrence of the protocol errors.

(4) Because the power control circuit 15 and the delay control circuit 16 are driven by the auxiliary power circuit 22, the control circuits can be operated in a stable and fast way.

### Second Embodiment

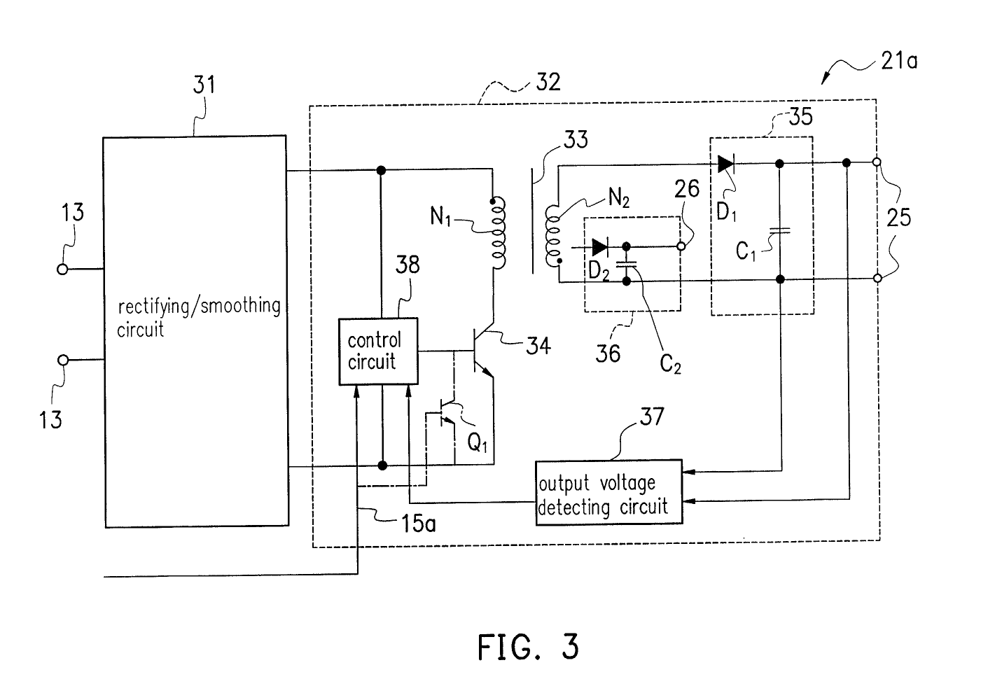

In the second embodiment, it shows an alternative main power circuit for the USB machine. FIG. 3 shows the alternative main power circuit 21a for replacing the main power circuit 21 in FIG. 1. In the second embodiment, all the other elements are the same as the first embodiment except the main power circuit 21a, and following description is referring to FIGS. 1 and 3. Referring to FIG. 3, the main power circuit 21a consists of a rectifying/smoothing circuit 31 and a switching regulator 32. The rectifying/smoothing circuit 31 is connected to the self-powered power terminal 13. The switching regulator 32 comprises a transformer 33, a switching device 34, a first output rectifying/smoothing circuit 35, a second output rectifying/smoothing circuit 36, an output voltage detecting circuit 37 and a control circuit 38. The switching device 34 is connected to the rectifying/smoothing circuit 31 through a primary winding N1 of the transformer 33. The first output rectifying/smoothing circuit 35 consists of a diode D1 and a capacitor C1, and is connected to a secondary winding N2 of the transformer 33 for sending out a voltage of 5V to an output terminal 25. The second output rectifying/smoothing circuit 36 consists of a diode D2 and a capacitor C2, and is connected to a portion of the secondary winding N2 of the transformer 33 for sending out a voltage of 3.3 V to an output terminal 26.

The output voltage detecting circuit 37 is used for detecting the voltage at the output terminal 25 and then the detected voltage is fedback to the control circuit 38 in order to maintain the voltage at the output terminal 25 at +5V. The control circuit 38 generates a PWM control signal in response to the output of the output voltage detecting circuit 37, for controlling the on/off state of the switching device 34 by a frequency of 20˜150 kHz for example. Additionally, the control circuit 38 controls the on/off state of the switching device 34 in response to the control signal from the power control circuit 15 in FIG. 1 through a line 15a. In other words, the control circuit 38 allows a constant voltage control operation of the switching device 34, which means that the switching device 34 is controlled by a constant voltage, in response to the detected result that the power control circuit 15 in FIG. 1 supplies the +5V voltage to the power terminal 10 of the USB port. When no voltage of +5V is supplied to the power terminal 10, the control circuit 38 disables the constant voltage control operation of the switching device 34 and then the switching device 34 is turned off to stop generating the output voltage. Therefore, the switching device 34 can perform both of the constant voltage control operation and the power switch function.

In addition to the advantages provided by the first embodiment, the second embodiment benefit other advantages. It provides an easy and simple way to supply or stop power from the main power circuit 21a.

The invention is not restricted to the foregoing embodiments, there are several alternations as follows for example.

(1) As a 3.3V power circuit 40 in dashed line in FIG. 1, it is connected to the +5V power terminal 10 of the USB port. The switch 18 and the pull-up resistor 17 can be connected in series between the signal line 8 and the 3.3V power circuit 40. In addition, the pull-up resistor 17 can be connected to the auxiliary power circuit 22.

(2) Instead of the auxiliary power circuit 22, the driving power of the power control circuit 15 and the delay control circuit 16 can be also from the +5V power terminal 10 of the USB port.

(3) For a simplified and easy description, the power control circuit 15 and the delay circuit 16 in FIG. 1 are two separated blocks. However, the power control circuit 15 and the delay circuit 16 can be also integrated together. In addition, all or a portion of the power control circuit 15 and the delay circuit 16 can be constructed by digital circuits. Furthermore, a microcomputer can be used to replace all or a portion of the power control circuit 15 and the delay circuit 16.

(4) Switches like the switch 23 can be assembled to the 5V output terminal 25 and the 3.3V output terminal 26 of the power circuit 24 in FIG. 1.

(5) As shown in FIG. 3, a switch Q1 in dashed line is connected between the control terminal of the switching device 34 and the ground and can be controlled by the signal from the line 15a. Accordingly, during the off state of the switch Q1, the constant voltage control operation for the switching device 34 can be performed, while during the on state of the switch Q1, the switching device is kept in the off state.

(6) The auxiliary power circuit 22 can be used to serve as a portion of the main power circuit 21, for example the rectifying/smoothing circuit.

(7) A power circuit for pull-up is set independently, and can be connected to the series-connection of the pull-up resistor 17 and the switch 18 between the power circuit for pull-up and the signal terminal 8 or 9.

While the present invention has been described with a preferred embodiment, this description is not intended to limit our invention. Various modifications of the embodiment will be apparent to those skilled in the art. It is therefore contemplated that the appended claims will cover any such modifications or embodiments as fall within the true scope of the invention.

What claimed is:

1. A self-powered USB machine, comprising
a USB port having signal terminals and power terminals;
a self-powered power terminal;
a control circuit receiving power from the self-powered power terminal or from the power terminals of the USB port, for detecting whether a voltage occurs at the power terminals of the USB port to generate a detected signal, and then outputting a control signal using the detected signal;
a USB power circuit coupled to the self-powered power terminal and the control circuit, for sending out a USB driving voltage in response to the control signal generated from the control circuit that indicates a voltage occurs at the power terminals of the USB port, and for stopping sending out the USB driving voltage in response to the control signal that indicates no voltage occurs at the power terminals of the USB port; and
a USB main entity coupled to the USB power circuit and the signal terminals of the USB port.

2. The self-powered USB machine of claim 1, further comprising:
a series-connected circuit consisting of a pull-up resistor and a pull-up switch for connecting the pull-up resistor, wherein the pull-up resistor is coupled between the signal terminals of the USB port and one of the USB power circuit, the power terminals of the USB port or a pull-up power circuit; and
a pull-up switch delay control circuit used for delaying a predetermined time from a time point of a signal generated to indicate that the USB power circuit sends out the USB driving voltage, thereby the pull-up switch is turned on after the predetermined time.

3. The self-powered USB machine of claim 1, further comprising an auxiliary power circuit for driving the control circuit, wherein the auxiliary power circuit is constantly connected to the self-powered power terminal.

4. The self-powered USB machine of claim 2, further comprising an auxiliary power circuit for driving the control circuit, wherein the auxiliary power circuit is constantly connected to the self-powered power terminal.

5. A self-powered USB machine, comprising
a USB port having signal terminals and power terminals;
a self-powered power terminal;
a control circuit receiving power from the self-powered power terminal or from the power terminals of the USB port, for detecting whether a voltage occurs at the power terminals of the USB port to generate a detected signal, and then outputting a control signal using the detected signal;
a USB power circuit coupled to the self-powered power terminal and the control circuit, for sending out a USB driving voltage in response to the control signal that indicates a voltage generated from the control circuit occurs at the power terminals of the USB port, and for stopping sending out the USB driving voltage in response to the control signal that indicates no voltage occurs at the power terminals of the USB port; and
a USB main entity coupled to the USB power circuit and the signal terminals of the USB port;
wherein the USB power circuit comprises a rectifying/smoothing circuit connected to the self-powered power terminal, and a switching regulator connected to the rectifying/smoothing circuit, and the switching regulator has a switching device for voltage regulation;
wherein the control circuit enables a voltage-control operation for the switching device in response to that a voltage occurs at the power terminals of the USB port, and disables the voltage-control operation to turn off the switching device to stop sending out the USB driving voltage in response to that no voltage occurs at the power terminals of the USB port.
